(19) United States
(12) Patent Application Publication
(10) Pub. No.: US 2005/0242855 A1
(43) Pub. Date: Nov. 3, 2005

(54) Delay locked loop circuit

(75) Inventor: Joong Ho Lee, Chungcheongbuk-do (KR)

Correspondence Address: LADAS & PARRY LLP, 224 SOUTH MICHIGAN AVENUE, SUITE 1600, CHICAGO, IL, 60604, US

(73) Assignee: Hynix Semiconductor Inc.

(21) Appl. No.: 11/086,054

(22) Filed: Mar. 22, 2005

(30) Foreign Application Priority Data
Apr. 29, 2004 (KR) 10-2004-0030252

(51) Int. Cl. H03L 7/06

(52) U.S. Cl. 327/158

(57) ABSTRACT

Disclosed is a delay locked loop circuit (DLL) used for DDR SDRAM. The DLL provides a fast locking function. In particular, the DLL detects the level of a frequency and performs the fast locking function, thereby realizing a high integrated memory device having a reduced area of a delay part used in order to synchronize a phase of an external clock signal with a phase of an internal clock.

### BACKGROUND OF THE INVENTION

1. Field of the Invention

The present invention relates to a delay locked loop circuit, and more particularly to a delay locked loop circuit capable of improving a signal processing time and reducing a device area.

2. Description of the Prior Art

As generally known in the art, a delay locked loop circuit synchronizes a phase of a clock signal externally applied to a semiconductor device with a phase of a clock signal used in the semiconductor device.

In particular, since the delayed locked loop circuit, which is used for high-speed synchronization memory devices such as DDR SDRAM, determines an operation frequency band of the memory devices and exerts serious influence on an operation time_characteristic, the high-speed synchronization memory devices include a high-performance delay locked loop circuit having a wide frequency band and a low jitter characteristic.

FIG. 1 illustrates a block diagram of a typical delayed locked loop circuit.

As shown in FIG. 1, the delay locked loop circuit includes a clock buffer 100 for receiving a clock signal /CLK, a clock buffer 101 for receiving an external clock signal CLK, a delay part 110 for receiving an output signal fclk2 of the clock buffer 100 and an output signal rclkt2 of the clock buffer 101, a delay part 120 for receiving output signals Fclk2_dly and Rclk2_dly of the delay part 110, a clock divider 130 for dividing the output signal rclkt2 of the clock buffer 101, a replica delay part 150 for receiving an output signal fb_dly2 of the delay part 120 and delaying the output signal fb_dly2 by a predetermined time, and a phase comparator 140 for comparing a phase of an output signal of the replica delay part 150 with a phase of an output signal ref of the clock divider 130.

The delay part 110 includes a plurality of delay lines 11 to 13, a shift register 13, and a shift controller 15. Also, the delay part 120 includes a plurality of delay lines 16 to 18, a shift register 19, and a shift controller 20.

Generally, the delay part 110 has a delay time longer than that of the delay part 120. That is, the delay part 110 adjusts a coarse delay time, and the delay part 120 adjusts a fine delay time.

The shift controller 15 receives an output signal of the phase comparator 140 and controls a shift register 14. The shift register 14 controls delay times of the delay lines 11 to 13.

A shift comparator 160 compares a phase of an output signal (ref) of the clock divider 130 with a phase of an output signal of a replica delay part 150 and is controlled by the shift controller 15.

The shift comparator 160 applies the output signal thereof to the shift controller 20. The shift controller 20 controls the shift register 19 so as to adjust a delay time of the delay lines 16 to 18.

A locking part 180 receives an output signal of the phase comparator 160 and an output signal Dll_lockz of the shift controller 20. Also, when output of the locking part 180 is enabled, the locking part 180 controls the shift register 19 so as to fix the delay time of the delay lines 16 to 18.

As shown in FIG. 1, a driver 170 receives an output signal of the delay line 16, and a driver 171 receives an output signal of the delay line 17. The drivers 170 and 171 output signals fclk_dll and rclk_dll.

As shown in FIG. 1, the CLK and /CLK denote external clock signals. A phase of the CLK is an inverted phase of the /CLK. The clock buffers 100 and 101 receive the external clock signals CLK and /CLK, and are buffer circuits for converting a voltage level of the clock buffers into a voltage level (e.g., CMOS level) used in a semiconductor device.

The delay part 110 delays the output signals fclk2 and rclkt2 of the clock buffers 100 and 101 by a predetermined time. As described above, the delay part 110 includes a plurality of the delay lines 11 to 13, and a delay time of the delay part 110 are controlled by the shift controller 15 and the shift register 14.

The clock divider 130 generates a predetermined reference clock by dividing a frequency of a clock signal rclkt2 outputted from the clock buffer 101 at the ratio of 1/n (generally, n may be ‘4’, ‘8’, ‘16’, etc as an integer).

The clock divider 130 applies an output signal ref thereof to the delay line 13 after delaying the output signal ref by a predetermined time. The output signal passing through the delay line 13 is applied to the delay line 18. The delay line 18 applies the output signal fb_dly2 thereof to the replica delay part 150.

The replica delay part 150 is a delay circuit having delay times tD1 and tD2 obtained by adding a delay time tD1 of the clock buffer 100 to a delay time tD2 of the output driver 170.

For reference, as shown in FIG. 1, the output signal fclk2 of the clock buffer 100 is outputted in synchronization with a rising edge of the external clock signal /CLK, and the output signal rclkt2 of the clock buffer 101 is outputted in synchronization with a rising edge of the external clock signal CLK. The output signal Fclk2_dly of the delay line 11 is a signal obtained by delaying the output signal fclk2 of the clock buffer 100 by a predetermined time, and the output signal Rclk2dly of the delay line 12 is a signal obtained by delaying the output signal rclkt2 of the clock buffer 101.

FIG. 2 illustrates the delay parts 110 and 120 by way of example in detail. That is, a delay part 200 shown in FIG. 2 is identical to delay parts 110 and 120 shown in FIG. 1.

As shown in FIG. 2, the delay part 200 includes a delay line 21. Signals RCLK, FCLK, and In_lock applied to the delay line 21 indicate the signals rclkt2, Rclk2_dly, fclk2, and Fclk2_dly applied to the delay lines shown in FIG. 1. A shift register 22 and a shift controller 23 shown in FIG. 2 indicate the shift registers 14 and 19 and the shift controllers 15 and 19 shown in FIG. 1.

As known to those skilled in the art, a delay time of a unit cell can be adjusted according to logical levels of an output signal outputted from a shift register.

Hereinafter, a basic operation of the conventional delay locked loop circuit shown in FIGS. 1 and 2 will be described.

The phase comparator 140 compares a phase of an output signal of the replica delay part 150 with a phase of an output signal ref of the clock divider 130 and sends a predetermined control signal to the shift controller 150. The shift register 15 controls the shift register 14, and the shift register 14 controls the delay lines 11 to 13. The delay part 120 performs an operation similar to that of the delay part 110. The above-mentioned procedure is repeated until there is no phase difference, which is a result of the phase comparator 140.

However, the conventional delay locked loop circuit shown in FIG. 1 has the following problems.

First, it is necessary to increase the number of unit delay circuits included in the delay line 102 in order to operate the delay locked loop circuit in a wide frequency band.

Also, if the number of the unit delay circuits is increased, an area occupied by the delay parts 110 and 120 is large.

In addition, the more the number of the unit delay circuits is, the more power consumption is.

### SUMMARY OF THE INVENTION

Accordingly, the present invention has been made to solve the above-mentioned problems occurring in the prior art, and an object of the present invention is to provide a delay locked loop circuit having a fast locking function and a relatively reduced delay line area.

Another object of the present invention is to provide a delay locked loop circuit having a fast locking function by including a unit for detecting levels of frequencies (lengths of periods) of external clock signals (CLK and CLKB).

In order to accomplish this object according to an aspect of the present invention, there is provided a delay locked loop circuit comprises a first delay part for receiving an external clock signal and outputting it after delaying a predetermined time; a first clock divider for dividing a frequency of the external clock signal into 1/n (n is a natural number of at least two); a second clock divider for dividing an output signal from the first delay part into 1/n (n is a natural number of at least two); and a second delay part for receiving an output signal from the second clock divider and outputting it after delaying a predetermined time; wherein the predetermined delay time of the first delay part is controllable by using a result of a phase difference between a phase of the output signal of the first clock divider and a phase of the output signal of the second delay part; and the output signal of the first delay part is an output signal of the delay locked loop circuit.

According to the present invention, the external clock signal is one of the signals CLK and /CLK which are input to a synchronous memory device. Also, the present invention further comprises a phase comparator for comparing the phase difference between a phase of the output signal of the first clock divider and a phase of the output signal of the second delay part; and a controller for controlling the predetermined delay time of the first delay part in response to an output signal of the phase comparator. Herein, when the phase of the output signal of the first clock divider is coincided with the phase of the output signal of the second delay part, the controller stops the operation of controlling the predetermined delay time of the first delay part.

In order to accomplish this object according to another aspect of the present invention, there is provided a delay locked loop circuit comprising: a first clock buffer for outputting a first clock signal in synchronization with a rising edge of an external clock signal; a second clock buffer for outputting a second clock signal in synchronization with a falling edge of the external clock signal; a multiplexer for selecting and outputting one of the first clock signal and the second clock signal; a first delay part for receiving an output signal of the multiplexer and having a first delay line, a first shift register, and a first shift controller; a second delay part for receiving an output signal of the first delay part and having a second delay line, a second shift register, and a second shift controller; a first clock divider for dividing a frequency of an output signal of the multiplexer into 1/n (n is a natural number of at least two); a second clock divider for dividing a frequency of an output signal of the second delay part into 1/n (n is a natural number of at least two); a third delay part for receiving an output signal of the second clock divider; a first phase comparator and a second phase comparator for comparing a phase of an output signal of the first clock divider with a phase of an output signal of the third delay part; and a delay time fine adjustment part for receiving the output signal of the second delay part and finely adjusting a phase of the output signal of the second delay part. According to the present invention, the first delay line receives the output signal of the multiplexer, the second delay line receives the output signal of the first delay line, the delay time fine adjustment part receives the output signal of the second delay line, the first shift controller received the output signal of the first phase comparator controls the first shift register and adjusts a delay time of the first delay line, and the second shift controller received the output signal of the second phase comparator controls the second shift register and adjusts a delay time of the second delay line.

According to the present invention, when the phase of the output signal of the first clock divider is synchronized with the phase of the output signal of the third delay part within allowance, the second shift controller controlled by the second phase comparator controls the second shift register so as to fix a delay time of the second delay line.

### BRIEF DESCRIPTION OF THE DRAWINGS

The above and other objects, features and advantages of the present invention will be more apparent from the following detailed description taken in conjunction with the accompanying drawings, in which:

FIG. 1 is a block diagram of a typical delay locked loop circuit;

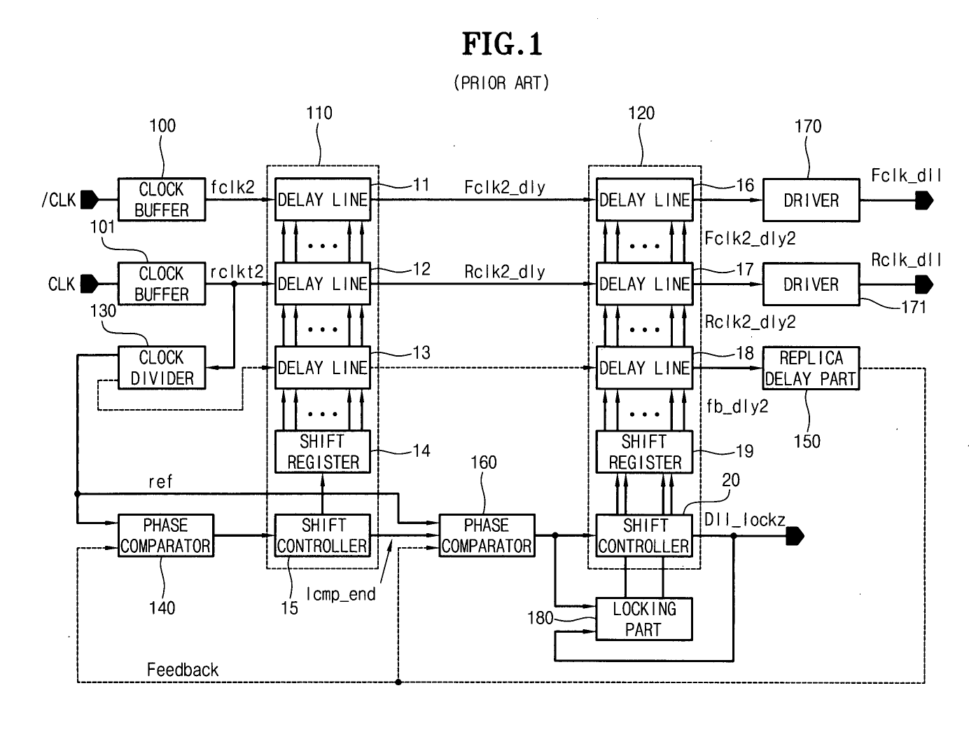

FIG. 2 illustrates delay parts shown in FIG. 1 by way of example in detail;

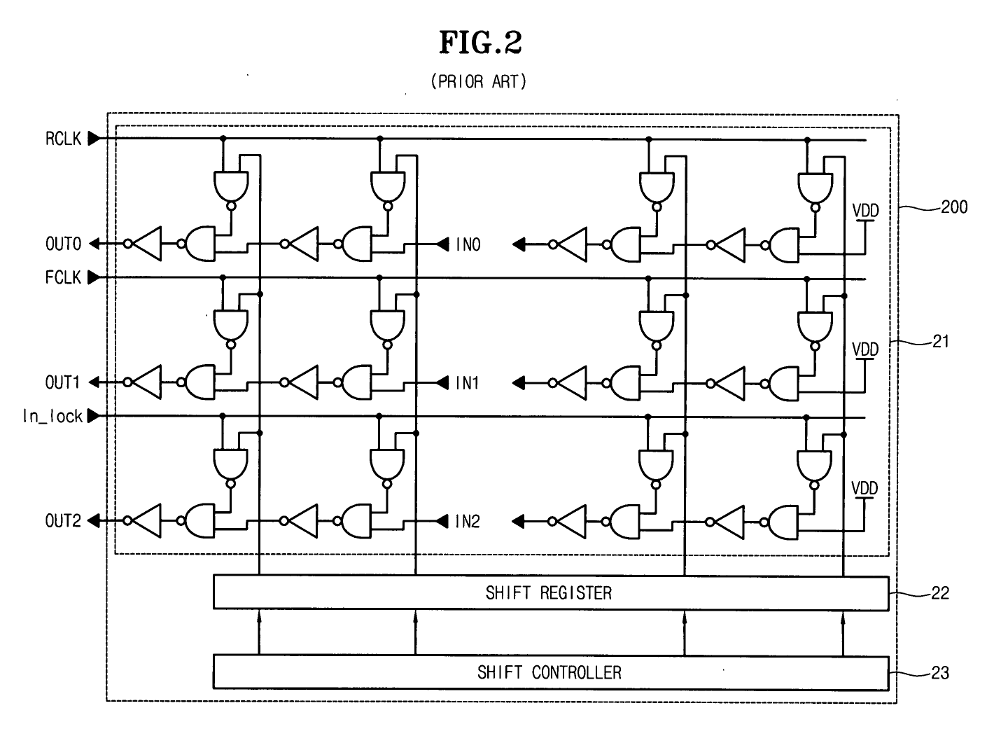

FIG. 3 is a block diagram of a delay locked loop circuit according to the present invention;

FIG. 4 illustrates a multiplexer and a delay part shown in FIG. 3 by way of example in detail; and

FIG. 5 illustrates a delay time fine adjustment shown in FIG. 3 by way of example.

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

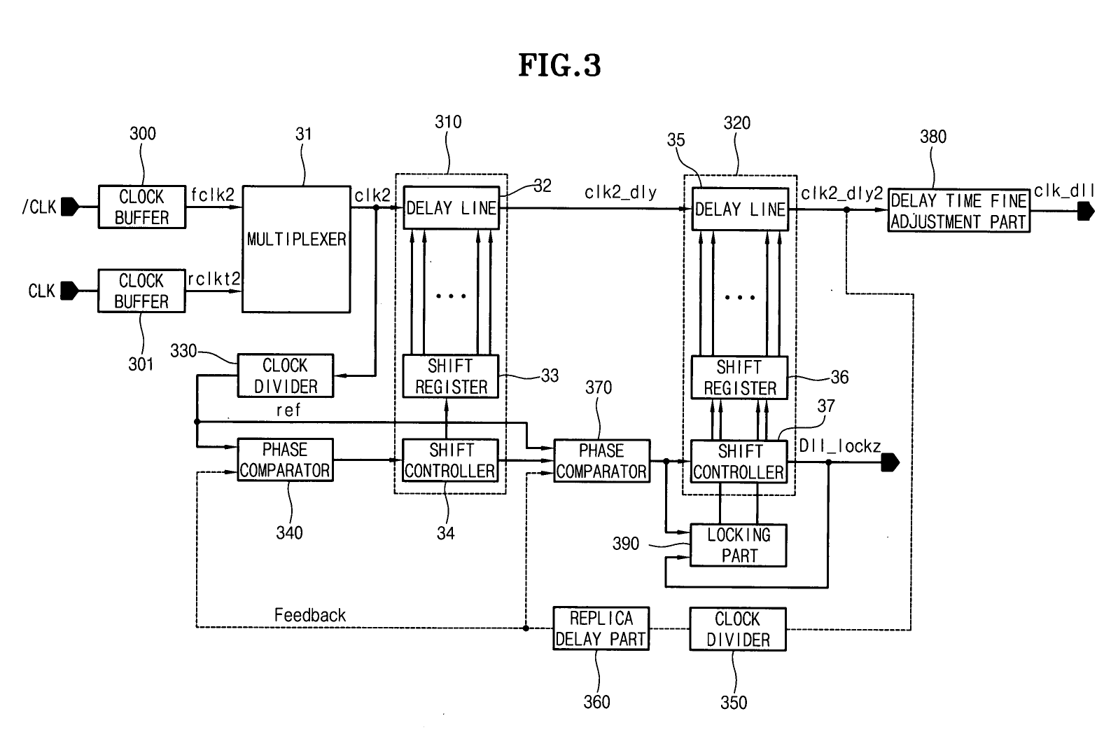

FIG. 3 illustrates a block diagram of a delay locked loop circuit according to the present invention.

As shown in FIG. 3, the delay locked loop circuit includes a clock buffer 300 for receiving an external clock signal /CLK, a clock buffer 301 for receiving an external clock signal CLK, a multiplexer 31 for receiving an output signal fclk2 of the clock buffer 300 and an output signal rclkt2 of the clock buffer 301, a delay part 310 for receiving an output signal clk2 of the multiplexer 31, a delay part 320 for receiving an output signal clk2_dly of the delay part 310, a clock divider 330 for receiving an output signal clk2 of the multiplexer 31, a clock divider 350 for receiving an output signal clk2_dly2 of the delay part 320, a replica delay part 360 for receiving an output signal of the clock divider 350, a phase comparator 340 for comparing a phase of an output signal Feedback of the replica delay part 360 with a phase of an output signal ref of the clock divider 130, a phase comparator 370 for comparing a phase of an output signal ref of the clock divider 330 with a phase of an output signal of a shift control part 34, and a delay time fine adjustment part 380 for receiving an output signal clk2_dly2 of the delay part 320 and finely adjusting a delay time.

As shown in FIG. 3, the delay part 310 includes a delay line 32, a shift register 33, and a shift controller 34. Also, the delay part 320 includes a delay line 35, a shift register 36, and a shift controller 37. The delay part 310 has a delay time longer than that of the delay part 320. That is, the delay part 310 adjusts a coarse delay time, and the delay part 320 adjusts a fine delay time.

The shift controller 34 receives an output signal of the phase comparator 340 and controls a shift register 33. The shift register 33 controls a delay time of the delay line 32.

The shift comparator 370 compares a phase of an output signal ref of the clock divider 330 with a phase of an output signal Feedback of a replica delay part 360.

The shift comparator 370 applies the output signal thereof to a shift controller 37. The shift controller 37 controls the shift register 36 so as to adjust a delay time of the delay line 35.

A locking part 390 receives an output signal of the phase comparator 370 and an output signal Dll_lockz of the shift controller 37. Also, when output of the locking part 390 is enabled, the locking part 390 controls the shift register 36 so as to fix the delay time of the delay line 35.

Hereinafter, signals of a circuit shown in FIG. 3 and an operation of each component of the circuit will be described.

As shown in FIG. 3, the CLK and the /CLK denote external clock signals. A phase of the CLK is an inverted phase of the /CLK. The clock buffers 300 and 301 receive the external clock signals CLK and /CLK, and are buffer circuits for converting a voltage level of the clock buffers into a voltage level (e.g., CMOS level) used in a semiconductor device. An output signal fclk2 of the clock buffer 300 is outputted in synchronization with a rising edge of the external clock signal /CLK, and an output signal rclkt2 of the clock buffer 301 is outputted in synchronization with a rising edge of the external clock signal CLK.

The multiplexer 31 selectively one of output signals of the clock buffers 300 and 301.

The multiplexer 31 applies an output signal clk2 to the delay part 310, and the delay part 310 applies an output signal clk2_dly to the delay part 320.

The delay part 320 applies an output signal clk_dly2 thereof to the delay time fine adjustment part 380. Also, the delay part 320 applies the output signal clk_dly2 to the clock divider 350. The signal clk_dly2 applied to the clock divider 350 is outputted to the clock divider 350 after the period thereof is increased by four times, eight times, etc. The clock divider 350 has the same division ratio as the clock divider 330.

The replica delay part 360 outputs the output signal of the clock divider 350 after delaying the output signal by a predetermined time.

The replica delay part 360 applies the output signal Feedback thereof to the phase comparators 340 and 370.

The phase comparator 340 compares a phase of a reference voltage ref outputted from the clock divider 330 with a phase of the output signal Feedback of the replica delay part 360. It is preferred that there is no phase difference.

The phase comparator 370 compares the phase of a reference voltage ref outputted from the clock divider 330 with the phase of the output signal Feedback of the replica delay part 360, and is controlled by the shift controller 34.

The phase comparator 370 applies an output signal thereof to the shift register 37 and the locking part 390.

The shift controller 37 controls the shift register 36 so as to finely adjust the delay line 35.

When an output signal Dll_lockz of the shift controller 37 is enabled to be a low level, the locking part 390 controls the shift register 36 so as to fix a delay time of the delay line 35.

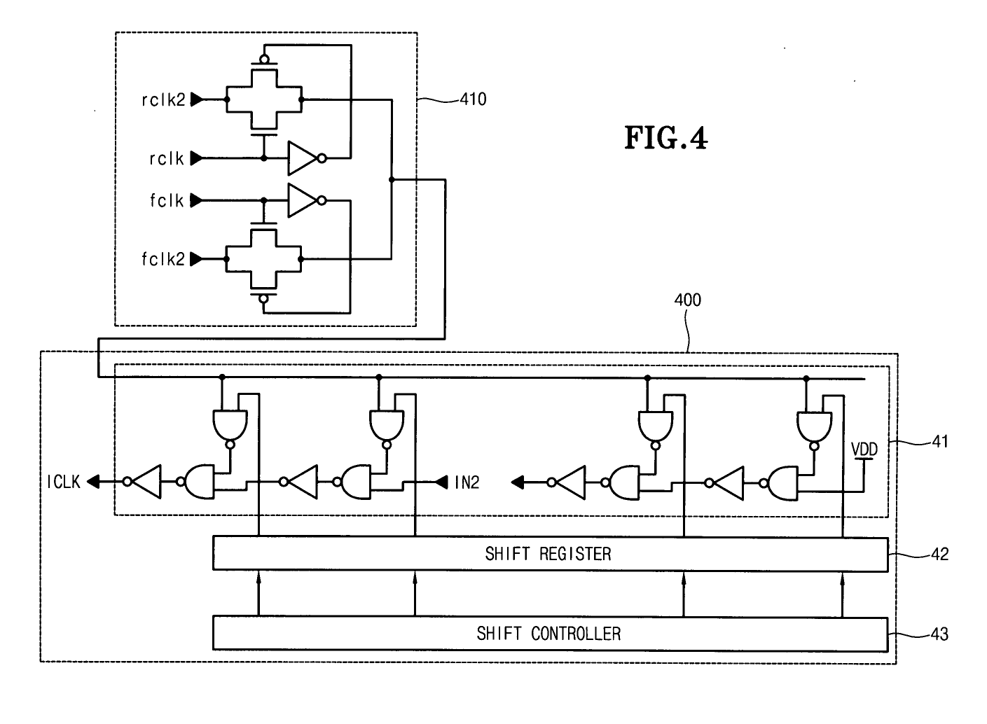

FIG. 4 illustrates the multiplexer 31 and the delay part 310 shown in FIG. 3 in detail by way of example. For reference, a multiplexer 410 and a delay part 400 shown in FIG. 4 correspond to the multiplexer 31 and the delay part 310 shown in FIG. 3, respectively. Also, a circuit of the delay part 400 shown in FIG. 4 is used for the delay part 320 shown in FIG. 3. A shift register 42 and a shift controller 43 shown in FIG. 4 imply shift registers 33 and 35 and shift controllers 34 and 37 shown in FIG. 3.

As shown in FIG. 4, the delay part 400 includes a delay line 41, the shift register 42, and the shift controller 43.

The multiplexer 410 selectively applies one of output signals rclk2 and fclk2 to the delay line 41 by using control signals rclk and fclk.

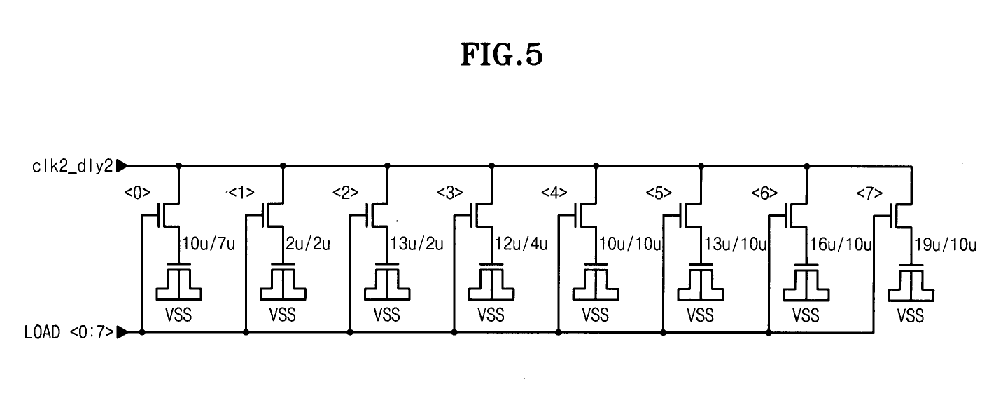

FIG. 5 illustrates the delay time fine adjustment part 380 shown in FIG. 3 by way of example.

As shown in FIG. 5, the delay time fine adjustment part 380 receives an output signal clk_dly2 of the delay line 35, and then, the output signal clk_dly2 is included in a circuit for an RC delay. As shown in FIG. 5, a control signal LOAD<0:7> applied to a transistor is selectively enabled, and a capacitor connected to each transistor is linked with a line for delivering the output signal clk_dly2, so that the RC delay is adjusted. Herein, the transistors may have the same sizes or difference sizes.

Hereinafter, an operation of the delay locked loop circuit according to the present invention with reference to FIGS. 3 to 5 will be described.

The delay locked loop circuit shown in FIG. 3 has an operation similar to that of a typical delay locked loop circuit.

As known to those skilled in the art, the delay locked loop circuit adjusts delay times of the delay lines 32 and 35 in such a manner that a phase of a signal passing through the clock divider 330 is synchronized with a phase of a signal passing through the replica delay part 360.

However, the delay locked loop circuit according to the present invention is different from the conventional delay locked loop circuit in view of a circuit structure, in that only one of the external clock signals CLK and /CLK is used in the delay locked loop circuit according to the present invention.

That is, as shown in FIG. 3, according to the present invention, one signal from the signals fclk2 and rclk2 passing through the clock buffers 300 and 301 is selected by means of the multiplexer 31 and applied to the delay line 32.

Accordingly, differently from the conventional technique, the number of delay lines included in the delay part is reduced. Therefore, an area of the delay part can be reduced.

Also, according to the present invention, the delay time fine adjustment part 380 is provided, so that a phase of an output signal of the delay line 320 is finely adjusted.

According to the present invention, the delay part 310 more precisely adjusts a delay time as compared with the delay part 320. That is, the delay part 310 adjusts a coarse delay time, and the delay part 320 more precisely adjusts a delay time.

The delay time fine adjustment part 380 adjusts a delay time more precisely than the delay part 320.

As described above, according to the present invention, a delay locked loop circuit is realized by using only one external clock signal, so that an area of a delay part can be minimized. Therefore, the delay locked loop circuit is useful in designing a high integrated circuit.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A delay locked loop circuit comprising:
a first delay part for receiving an external clock signal and outputting it after delaying a predetermined time;
a first clock divider for dividing a frequency of the external clock signal into 1/n (n is a natural number of at least two);
a second clock divider for dividing an output signal from the first delay part into 1/n (n is a natural number of at least two); and
a second delay part for receiving an output signal from the second clock divider and outputting it after delaying a predetermined time;
wherein the predetermined delay time of the first delay part is controllable by using a result of a phase difference between a phase of the output signal of the first clock divider and a phase of the output signal of the second delay part; and
the output signal of the first delay part is an output signal of the delay locked loop circuit.

2. The delay locked loop circuit claimed in claim 1, wherein the external clock signal is one of the signals CLK and /CLK which are input to a synchronous memory device.

3. The delay locked loop circuit claimed in claim 1, further comprising;
a phase comparator for comparing the phase difference between a phase of the output signal of the first clock divider and a phase of the output signal of the second delay part; and
a controller for controlling the predetermined delay time of the first delay part in response to an output signal of the phase comparator.

4. The delay locked loop circuit claimed in claim 3, wherein when the phase of the output signal of the first clock divider is coincided with the phase of the output signal of the second delay part, the controller stops the operation of controlling the predetermined delay time of the first delay part.

5. A delay locked loop circuit comprising:
a first clock buffer for outputting a first clock signal in synchronization with a rising edge of an external clock signal;
a second clock buffer for outputting a second clock signal in synchronization with a falling edge of the external clock signal;
a multiplexer for selecting and outputting one of the first clock signal and the second clock signal;
a first delay part for receiving an output signal of the multiplexer and having a first delay line, a first shift register, and a first shift controller;
a second delay part for receiving an output signal of the first delay part and having a second delay line, a second shfit register, and a second shift controller;
a first clock divider for dividing a frequency of an output signal of the multiplexer into 1/n (n is a natural number of at least two);
a second clock divider for dividing a frequency of an output signal of the second delay part into 1/n (n is a natural number of at least two);
a third delay part for receiving an output signal of the second clock divider;
a first phase comparator and a second phase comparator for comparing a phase of an output signal of the first clock divider with a phase of an output signal of the third delay part; and
a delay time fine adjustment part for receiving the output signal of the second delay part and finely adjusting a phase of the output signal of the second delay part.

6. The delay locked loop circuit as claimed in claim 5, wherein the first delay line receives the output signal of the multiplexer, the second delay line receives the output signal of the first delay line, the delay time fine adjustment part receives the output signal of the second delay line, the first shift controller received the output signal of the first phase comparator controls the first shift register and adjusts a delay time of the first delay line, and the second shift controller received the output signal of the second phase comparator controls the second shift register and adjusts a delay time of the second delay line.

7. The delay locked loop circuit claimed in claim 6, wherein, when the phase of the output signal of the first clock divider is synchronized with the phase of the output signal of the third delay part within allowance, the second shift controller controlled by the second phase comparator controls the second shift register so as to fix a delay time of the second delay line.

8. The delay locked loop circuit claimed in claim 6, wherein the second delay part adjusts a delay time more precisely than the first delay part, and the delay time fine adjustment part adjusts a delay time more precisely than the second delay part.
